(19) United States
(12) Patent Application Publication
(10) Pub. No.: US 2016/0276196 A1
(43) Pub. Date: Sep. 22, 2016

(54) CERAMIC ELECTROSTATIC CHUCK BONDED WITH HIGH TEMPERATURE POLYMER BOND TO METAL BASE

(71) Applicant: Applied Materials, Inc., Santa Clara, CA (US)

(72) Inventor: Vijay D. PARKHE, San Jose, CA (US)

(21) Appl. No.: 14/997,852

(22) Filed: Jan. 18, 2016

Related U.S. Application Data
(60) Provisional application No. 62/137,264, filed on Mar. 24, 2015.
(60) Provisional application No. 62/136,351, filed on Mar. 20, 2015.

(51) Int. Cl. H01L 21/683; H01L 21/67

(52) U.S. Cl. CPC H01L 21/6831; H01L 21/67103

(57) ABSTRACT

Implementations described herein provide a substrate support assembly which enables high temperature processing. The substrate support assembly includes an electrostatic chuck secured to a cooling base by a bonding layer. The bonding layer has a first layer and a second layer. The first layer has an operating temperature that includes a temperature of about 300 degrees Celsius. The second layer having a maximum operating temperature that is below 250 degrees Celsius.

### CROSS-REFERENCE TO RELATED APPLICATIONS

This application claims benefit of U.S. Provisional Application Ser. No. 62/136,351, filed Mar. 20, 2015 (Attorney Docket No. APPM/22729USL), and U.S. Provisional Application Ser. No. 62/137,264, filed Mar. 24, 2015 (Attorney Docket No. APPM/22729USL02), both of which are incorporated by reference in their entirety.

### BACKGROUND

1. Field

Implementations described herein generally relate to semiconductor manufacturing and more particularly to a substrate support assembly suitable for high temperature semiconductor manufacturing.

2. Description of the Related Art

Reliably producing nanometer and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI interconnect technology have placed additional demands on processing capabilities. Reliable formation of gate structures on the substrate is important to VLSI and ULSI success and to the continued effort to increase circuit density and quality of individual substrates and die.

To drive down manufacturing cost, integrated chip (IC) manufactures demand higher throughput and better device yield and performance from every silicon substrate processed. Some fabrication techniques being explored for next generation devices under current development require processing at temperatures above 300 degrees Celsius. Conventional electrostatic chucks are typically bonded to a cooling plate in the substrate support assembly, wherein the dielectric properties of the bond is sensitive to high temperatures. However, conventional electrostatic chucks may experience bonding problems within the substrate support assemblies at temperatures approaching 250 degrees Celsius or more. The bond may gas out into the processing volume causing contamination in the chamber or could have delamination issues. Additionally, the bond may fail altogether causing a loss of vacuum or movement in the substrate support. The chamber may require down time to fix these defects, effecting costs, yield and performance.

Thus, there is a need for an improved substrate support assembly suitable for use at processing temperatures at or above 250 degrees Celsius.

### SUMMARY

Implementations described herein provide a substrate support assembly which enables high temperature processing. The substrate support assembly includes an electrostatic chuck secured to a cooling base by a bonding layer. The bonding layer has a first layer and a second layer. The first layer has an operating temperature that includes a temperature of about 300 degrees Celsius. The second layer having a maximum operating temperature that is below 250 degrees Celsius.

In another implementation, the substrate support assembly includes an electrostatic chuck secured to a cooling base by a bonding layer. The bonding layer has a first layer, a second layer and a third layer. The first layer is in contact with the electrostatic chuck and has an operating temperature that includes a temperature of about 300 degrees Celsius. The second layer is disposed between the first and third layers, and has a maximum operating temperature that is below 250 degrees Celsius. The third layer is disposed in contact with the cooling plate and has a maximum operating temperature that is lower that of the second layer.

In yet another implementation, the substrate support assembly includes an electrostatic chuck secured to a cooling base. A metal plate disposed below a bottom surface of the electrostatic chuck. A bonding layer is disposed between the metal plate and a top surface of the cooling plate. The bonding layer has a first layer and a second layer. The first layer is in contact with the electrostatic chuck and has an operating temperature that includes a temperature of about 300 degrees Celsius. The second layer has a maximum operating temperature that is below 250 degrees Celsius.

### BRIEF DESCRIPTION OF THE DRAWINGS

So that the manner in which the above recited features of the present invention can be understood in detail, a more particular description of the invention, briefly summarized above, may be had by reference to implementations, some of which are illustrated in the appended drawings. It is to be noted, however, that the appended drawings illustrate only typical implementations of this invention and are therefore not to be considered limiting of its scope, for the invention may admit to other equally effective implementations.

FIG. 1 is a cross-sectional schematic side view of a processing chamber having one embodiment of a substrate support assembly.

FIG. 2 is a partial cross-sectional schematic side view of the substrate support assembly detailing one embodiment of a bonding layer disposed between an electrostatic substrate support and a cooling base.

FIG. 3 illustrates an electrical socket in a bottom view of the electrostatic substrate support.

FIG. 4 is a partial cross-sectional schematic side view of the substrate support assembly detailing another embodiment of the bonding layer disposed between the electrostatic substrate support and the cooling base.

To facilitate understanding, identical reference numerals have been used, where possible, to designate identical elements that are common to the figures. It is contemplated that elements disclosed in one implementation may be beneficially used in other implementations without specific recitation.

### DETAILED DESCRIPTION

Implementations described herein provide a substrate support assembly which enables high temperature operation of an electrostatic chuck. High temperature is intended to refer to temperatures in excess of about 150 degrees Celsius, for example, temperatures in excess of about 250 degrees Celsius, such as temperatures of about 250 degrees Celsius to about 300 degrees Celsius. The substrate support assembly has an electrostatic chuck bonded to a cooling base by a bonding layer. The bonding layer is formed from several distinct layers that enable operation of the electrostatic chuck at high temperatures. At least one of the distinct layers has a low thermal conductivity (i.e., a thermal conductivity less than about 0.2 W/mK) to minimize heat transfer across from an interface between the electrostatic chuck and the cooling plate. The materials comprising the layers are also selected to prevent failure of the bonding layer securing the electrostatic chuck to the cooling base at temperatures above about 150 degrees Celsius, such as temperatures above about 250 degrees Celsius. Although the substrate support assembly is described below in an etch processing chamber, the substrate support assembly may be utilized in other types of plasma processing chambers, such as physical vapor deposition chambers, chemical vapor deposition chambers, ion implantation chambers, among others, and other systems where high temperature (i.e., temperatures exceeding 150 degrees) processing occurs.

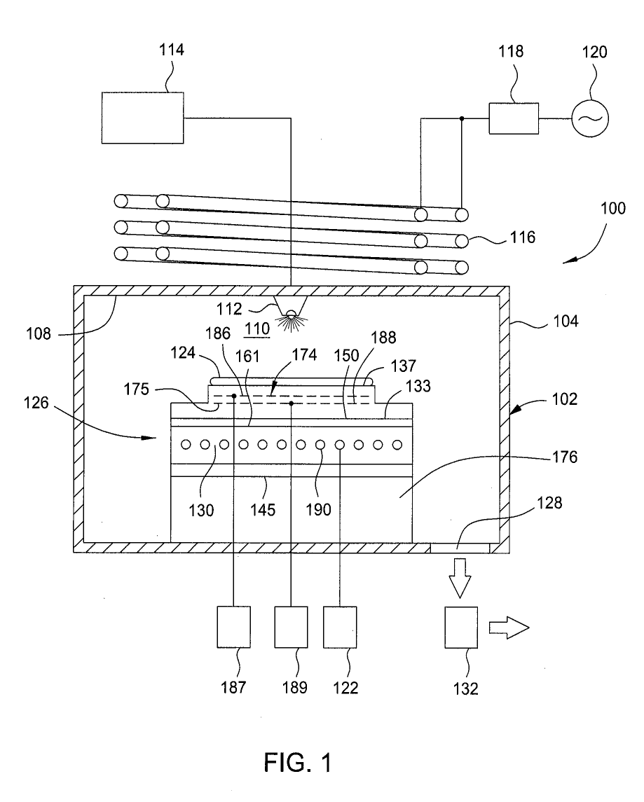

FIG. 1 is a cross-sectional schematic view of an exemplary plasma processing chamber 100, shown configured as an etch chamber, having a substrate support assembly 126. The substrate support assembly 126 may be utilized in other types of processing plasma chambers, for example plasma treatment chambers, annealing chambers, physical vapor deposition chambers, chemical vapor deposition chambers, and ion implantation chambers, among others, as well as other systems where the ability to control processing uniformity for a surface or workpiece, such as a substrate, is desirable. Control of the dielectric properties tan(δ), i.e., dielectric loss, or ρ, i.e., the volume resistivity, for the substrate support at elevated temperature ranges and beneficially enables azimuthal processing uniformity for a substrate 124 thereon.

The plasma process chamber 100 includes a chamber body 102 having sidewalls 104, a bottom 106 and a lid 108 that enclose a processing region 110. An injection apparatus 112 is coupled to the sidewalls 104 and/or lid 108 of the chamber body 102. A gas panel 114 is coupled to the injection apparatus 112 to allow process gases to be provided into the processing region 110. The injection apparatus 112 may be one or more nozzle or inlet ports, or alternatively a showerhead. Processing gas, along with any processing by-products, are removed from the processing region 110 through an exhaust port 128 formed in the sidewalls 104 or bottom 106 of the processing chamber body 102. The exhaust port 128 is coupled to a pumping system 132, which includes throttle valves and pumps utilized to control the vacuum levels within the processing region 110.

The processing gas may be energized to form a plasma within the processing region 110. The processing gas may be energized by capacitively or inductively coupling RF power to the processing gases. In the embodiment depicted in FIG. 1, a plurality of coils 116 are disposed above the lid 108 of the plasma processing chamber 100 and coupled through a matching circuit 118 to an RF power source 120.

The substrate support assembly 126 is disposed in the processing region 110 below the injection apparatus 112. The substrate support assembly 126 includes an electrostatic chuck 174 and a cooling base 130. The cooling base 130 is supported by a base plate 176. The base plate 176 is supported by one of the sidewalls 104 or bottom 106 of the processing chamber. The substrate support assembly 126 may additionally include a heater assembly (not shown). Additionally, the substrate support assembly 126 may include a facility plate 145 and/or an insulator plate (not shown) disposed between the cooling base 130 and the base plate 176.

The cooling base 130 may be formed from a metal material or other suitable material. For example, the cooling base 130 may be formed from aluminum (Al). The cooling base 130 may include cooling channels 190 formed therein. The cooling channels 190 may be connected to a heat transfer fluid source 122. The heat transfer fluid source 122 provides a heat transfer fluid, such as a liquid, gas or combination thereof, which is circulated through one or more cooling channels 190 disposed in the cooling base 130. The fluid flowing through neighboring cooling channels 190 may be isolated to enabling local control of the heat transfer between the electrostatic chuck 174 and different regions of the cooling base 130, which assists in controlling the lateral temperature profile of the substrate 124. In one embodiment, the heat transfer fluid circulating through the channels 190 of the cooling base 130 maintains the cooling base 130 at a temperature between about 90 degrees Celsius and about 80 degrees Celsius, or at a temperature lower than 90 degrees Celsius.

The electrostatic chuck 174 includes a chucking electrode 186 disposed in a dielectric body 175. The dielectric body 175 has a workpiece support surface 137 and a bottom surface 133 opposite the workpiece support surface 137. The dielectric body 175 of the electrostatic chuck 174 may be fabricated from a ceramic material, such as alumina (Al₂O₃), aluminum nitride (AlN) or other suitable material. Alternately, the dielectric body 175 may be fabricated from a polymer, such as polyimide, polyetheretherketone, polyaryletherketone and the like.

The dielectric body 175 may also include one or more resistive heaters 188 embedded therein. The resistive heaters 188 may be provided to elevate the temperature of the substrate support assembly 126 to a temperature suitable for processing a substrate 124 disposed on the workpiece support surface 137 of the substrate support assembly 126. The resistive heaters 188 are coupled through the facility plate 145 to a heater power source 189. The heater power source 189 may provide 900 watts or more power to the resistive heaters 188. A controller (not shown) may control the operation of the heater power source 189, which is generally set to heat the substrate 124 to a predefined temperature. In one embodiment, the resistive heaters 188 include a plurality of laterally separated heating zones, wherein the controller enables at least one zone of the resistive heaters 188 to be preferentially heated relative to the resistive heaters 188 located in one or more of the other zones. For example, the resistive heaters 188 may be arranged concentrically in a plurality of separated heating zones. The resistive heaters 188 may maintain the substrate 124 at a temperature suitable for processing, such as between about 180 degrees Celsius to about 500 degrees Celsius, such as greater than about 250 degrees Celsius, such as between about 250 degrees Celsius and about 300 degrees Celsius.

The electrostatic chuck 174 generally includes a chucking electrode 186 embedded in the dielectric body 175. The chucking electrode 186 may be configured as a mono polar or bipolar electrode, or other suitable arrangement. The chucking electrode 186 is coupled through an RF filter to a chucking power source 187, which provides a RF or DC power to electrostatically secure the substrate 124 to the workpiece support surface 137 of the electrostatic chuck 174. The RF filter prevents RF power utilized to form a plasma (not shown) within the plasma processing chamber 100 from damaging electrical equipment or presenting an electrical hazard outside the chamber.

The workpiece support surface 137 of the electrostatic chuck 174 may include gas passages (not shown) for providing backside heat transfer gas to the interstitial space defined between the substrate 124 and the workpiece support surface 137 of the electrostatic chuck 174. The electrostatic chuck 174 may also include lift pin holes for accommodating lift pins (not shown) for elevating the substrate 124 above the workpiece support surface 137 of the electrostatic chuck 174 to facilitate robotic transfer into and out of the plasma processing chamber 100.

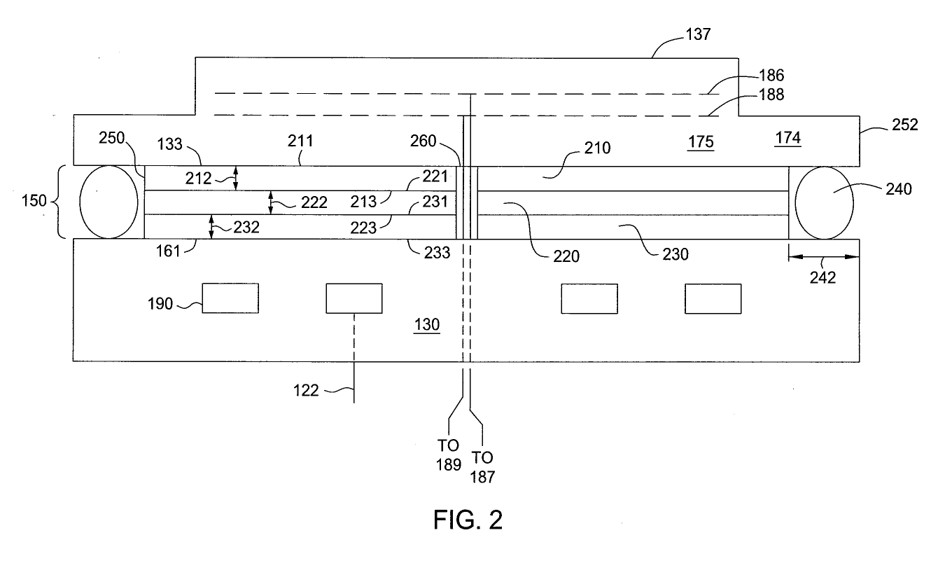

A bonding layer 150 is disposed between the electrostatic chuck 174 and the cooling base 130. The bonding layer 150 may have a thermal conductivity between about 0.1 W/mK and about 1 W/mk, such as about 0.17 W/mK. The bonding layer 150 may be formed from several layers which provide for different thermal expansions of the electrostatic chuck 174 and the cooling base 130. The layers comprising the bonding layer 150 may be formed from different materials and is discussed in reference to FIG. 2. FIG. 2 is a partial cross-sectional schematic side view of the substrate support assembly 126 detailing one embodiment of the bonding layer 150 disposed between the electrostatic chuck 174 and the cooling base 130.

An electrical socket 260 may provide connections to the resistive heaters 188 and chucking electrode 186 embedded in the dielectric body 175. The resistive heaters 188 may heat the bottom 133 of the electrostatic chuck 174 to temperatures above 250 degrees Celsius.

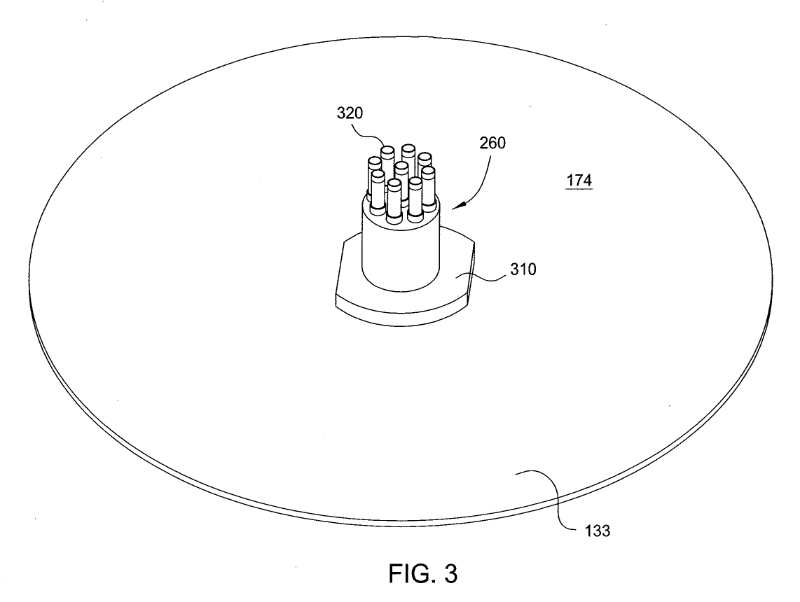

Turning briefly to FIG. 3, FIG. 3 illustrates the electrical socket 260 in a bottom view of the electrostatic chuck 174. The electrical socket 260 may have a housing 310 and a plurality of connectors 320. The connectors 320 provide electrical continuity to the heaters and the chucking electrode. The connectors 320 are embedded in the housing 310.

The housing 310 may be formed from a material having a low thermal conductivity. In one embodiment, the housing 310 is formed from a polyimide material such as MELDIN®, VESPEL®, or REXOLITE® or other suitable material. The housing 310 may have a thermal coefficient of expansion between about 3.0×10⁻⁵/C and about 5×10⁻⁵/C. The housing may have a thermal conductivity of about 0.2 W/mK to about 1.8 W/mK. The housing 310 may insulate the connectors 320 from the high temperatures from the electrostatic chuck 174.

Returning back to FIG. 2, the electrical socket 260 may extend through the bonding layer 150 and interface with the cooling base 130.

The bonding layer 150 is disposed between and attached/bonded to the cooling base 130 and the electrostatic chuck 174. The bonding layer 150 may have a temperature gradient of between about 60 degrees Celsius to about 250 degrees Celsius between the bottom surface 133 of the electrostatic chuck 174 and the top surface 161 of the cooling base 130. The bonding layer 150 may extend to about an outer diameter 252 of the electrostatic chuck 174 and the cooling base 130. The bonding layer 150 is flexible to account for thermal expansion between the electrostatic chuck 174 and the cooling base 130 and prevents cracking or the bond breaking free of the electrostatic chuck 174 or cooling base 130.

The bonding layer 150 may consist of two or more material layers. The bonding layer 150 may optionally include one or more o-rings. In one embodiment, the bonding layer 150 includes a first layer 210, a second layer 220, and a third layer 230. However, in other embodiments, the bonding layer 150 may include the first layer 210 and second layer 220 or the second layer 220 and third layer 230. The bonding layer 150 may include more than three layers. The operation of the two or more layers in the bonding layer 150 will be described below using the first layer 210 and second layer 220 and the third layer 230.

The first layer 210, second layer 220, and third layer 230 may have an outer periphery 250. The bonding layer 150 may additionally include an o-ring 240 disposed about the outer periphery 250 of the first layer 210, second layer 220, and third layer 230. A space 242 is formed between the outer periphery 250 and the outer diameter 252 of the electrostatic chuck 174. The space 242 may be sized to permit the o-ring 240 to sealingly engage the electrostatic chuck 174 and cooling base 130. In one embodiment, the bonding layer 150 includes one or more or the first layer 210, the second layer 220, the third layer 230, and the o-ring 240.

The o-ring 240 may be formed from a perfluoro elastomer material or other suitable material. For example, the material of the o-ring 240 may be a CHEMRAZ® or XPE® sealing o-ring. The material of the o-ring 240 may have a sufficiently soft Shore hardness of about 70 durometers for making a vacuum seal. The o-ring 240 may form a vacuum tight seal against the electrostatic chuck 174 and the cooling base 130. The vacuum tight seal formed by the o-ring 240 may prevent the loss of the vacuum for the process environment through the substrate support assembly 126. Additionally, the o-ring 240 may protect the inner portions of the substrate support assembly 126 from exposure to the plasma environment. That is, the o-ring 240 protects the first layer 210, second layer 220, and third layer 230 of the bonding layer 150 from the plasma. The o-ring 240 may additionally prevent volatized gases from the first layer 210, second layer 220, and third layer 230 from contaminating the plasma environment. Alternately, the first layer 210, second layer 220, and third layer 230 are bonded with the electrostatic chuck 174 and cooling base 130 and form a vacuum seal without the o-ring 240.

The first layer 210 may have a top surface 211 and a bottom surface 213. The top surface 211 is in contact with the bottom surface 133 of the electrostatic chuck 174. The top surface 211 of the first layer 210 may be at a temperature of the bottom surface 133 of the electrostatic chuck 174, i.e., about 150 degrees Celsius to about 300 degrees Celsius. To accommodate the high temperature of the electrostatic chuck, the first layer 210 may be fabricated from a material having an operating temperature that that exceed 150 degrees Celsius. For example, the first layer 210 may be fabricated from a material includes an operating temperature of about 250 degrees, or in another example, includes an operating temperature of about 300 degrees Celsius. In still another example, the first layer 210 may be fabricated from a material has an operating temperature that includes temperatures between about 250 degrees Celsius and about 325 degrees Celsius.

The bottom surface 213 may be in contact with the second layer 220. The first layer 210 may form a high temperature bonding layer with the bottom surface 133 of the electrostatic chuck 174. The first layer 210 may additionally be bonded to the second layer 220. The first layer 210 may be formed from a perfluoro compound or other suitable high temperature compound. For example, the first layer 210 may be formed from perfluoromethyl vinyl ether, alkoxy vinyl ether, TEFZEL® or other suitable bonding agent. The first layer 210 may be formed from a high temperature silicone. Advantageously, the fluorine-carbon bonds of the perfluoro compounds are extremely stabile conferring high thermal and chemical stability. The perfluoro compounds adhere to ceramics well, are not rigid, have minimal compression and have the ability to take strain. The first layer 210 is configured to thermal expand with the expansion of the electrostatic chuck 174 due to high operating temperatures, such as operating temperatures exceeding 150 degrees Celsius, such as operating temperatures upward of about 250 degrees Celsius. The first layer 210 may be sized to the bottom surface 133 of the electrostatic chuck 174. Alternately, the first layer may be sized to provide sufficient space for the o-ring 240 to sealing engage the electrostatic chuck 174.

The first layer 210 may be formed in sheets. The first layer 210 may have a thickness 212 of less than about 1 mm, such as about 5 mils (about 0.127 mm). In one embodiment, the first layer 210 may be a perfluoropolymer bonding agent suitable for temperatures exceeding 300 degrees Celsius. The first layer 210 may have a thermal conductivity selected for high processing temperatures in a range from 0.1 to 0.5 W/mK. In one exemplary embodiment, the thermal conductivity of the first layer 210 is about 0.24 W/mK.

The second layer 220 is separated from the high temperature of the electrostatic chuck 174 by the first layer 210. Thus, the second layer 220 may have an operating temperate less than that of the first layer 210. For example, the maximum operating temperate the second layer 220 may be less than that of the first layer 210. In another example, the maximum operating temperate the second layer 220 may be less than about 250 degrees Celsius.

The second layer 220 may have a top surface 221 and a bottom surface 223. The top surface 221 of the second layer 220 contacts the bottom surface 213 of the first layer 210. The top surface 221 may optionally form a high temperature bond with the bottom surface 213 of the first layer 210. The bottom surface 223 of the second layer 220 may be in contact with the third layer 230. The second layer 220 forms a bond with the bottom surface 213 of the first layer 210 and the second layer 220. In one example, the second layer 220 may be a material, which doesn't have to be an adhesive, having a rigidity greater than a rigidity of the top layer 210. The second layer 220 may be formed from a polyimide, perfluoro compound, silicone, or other suitable high temperature material. For example, the second layer 220 may be formed from CIRLEX®, TEFZEL®, KAPTON®, VESPEL®, KERIMID®, polyethylene, or other suitable material. The polyimide sheets are more rigid than the perfluoro sheets and also have a lower thermal expansion and conductance then the perfluoro sheets. Advantageously, the material selected for the second layer 220 has a low thermal conductance and acts as a thermal insulator. The lower the thermal conductance of the second layer 220, the greater a potential temperature differential across the second layer 220.

The second layer 220 may have a thickness 222 of between about 1 mm and about 3 mm, such as about 1.5 mm. In one embodiment, the second layer 220 is a polyimide sheet. The second layer 220 may have a coefficient of thermal conductivity selected in a range from about 0.1 to about 0.35 W/mK, and in one exemplary embodiment, about 0.17 W/mK.

The third layer 230 is separated from the high temperature of the electrostatic chuck 174 by the first and second layers 210, 220. Thus, the third layer 230 may have an operating temperate less than that of the second layer 220. For example, the maximum operating temperate the third layer 230 may be less than that of the second layer 220. In another example, the maximum operating temperate the third layer 230 may be less than about 200 degrees Celsius.

The third layer 230 may have a top surface 231 and a bottom surface 233. The third layer 230 may be disposed between the second layer 220 and the cooling base 130. The top surface 231 of the third layer 230 may optionally be bonded to the bottom surface 223 of the second layer 220 and the bottom surface 233 of the third layer 230 may optionally be bonded to the cooling base 130. The bottom surface 233 of the third layer may be at a temperature of the cooling base 130, i.e., between about 80 degrees Celsius and about 60 degrees Celsius. In one embodiment, the third layer 230 forms a low temperature bonding layer with the cooling base 130.

The third layer 230 may be formed from perfluoro compound, silicone, porous graphite or an acrylic compound or other suitable material. The material for the third layer 230 is selected based on the low operating temperatures, i.e., about 80 degrees, the third layer 230 is exposed to and optionally the material the third layer 230 may bond to. The third layer 230 is protected from the high heat of the electrostatic chuck 174 from one of the first layer 210 or the second layer 220. Thus, in embodiments where the material of the third layer 230 is a silicone, the first layer 210 and/or second layer 220 prevent the silicone material of the third layer 230 from outgassing or volatizing. The third layer 230 may have a thickness 232 of less than about 1 mm, such as about 5 mils (about 0.127 mm). In one embodiment, the third layer 230 is a silicone material. The third layer 230 may a coefficient of thermal expansion maybe in a range from about 2.0 to about 7.8×10⁻⁶/C. The third layer 230 may have a coefficient of thermal conductivity selected in a range from about 0.10 to about 0.4 W/mK, and in one exemplary embodiment, about 0.12 W/mK.

Advantageously, the bonding layer 150 contains layers having distinct properties which create a gradient for the coefficient of thermal expansion and thermal conductivity from the electrostatic chuck 174 and cooling base 130. The bonding layer 150 may create a vacuum seal to prevent outgassing of the chamber through the substrate support assembly 126. Additionally, the flexibility of polymer, low modulus of elasticity of the bonding layer 150, in those embodiments wherein the bonding layer is bonded to the electrostatic chuck 174 and the cooling base 130, mitigates cracking or breaking of the bonds and/or bonding layer 150 due to the large temperature gradient from the electrostatic chuck 174 to the cooling base 130. Therefore, the bonding layer 150 minimizes the need for downtime to repair the substrate support assembly 126 due to damage due to heat induced stress at adjoining locations having dissimilar thermal expansion due to large temperature gradients.

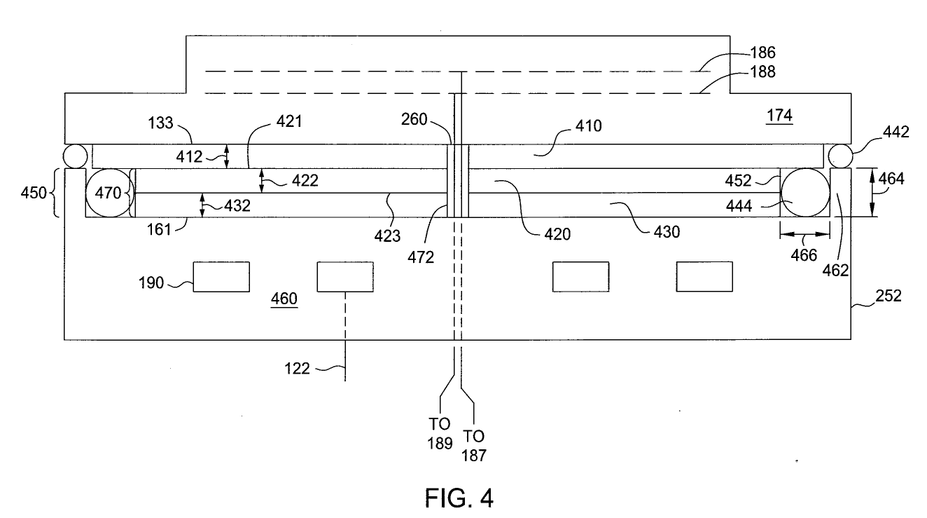

FIG. 4 presents a second embodiment for the bonding layer 150 and is a partial cross-sectional schematic side view of the substrate support assembly 126 detailing the second embodiment of the bonding layer 450 disposed between the electrostatic chuck 174 and a cooling base 460. The cooling base 460 is similarly configured to cooling base 130. Cooling base 460 additionally has a lip 462 disposed at the outer diameter 252 of the cooling base 460. The lip 462 may have a height 464 above the top surface 161 similar to the thickness of the bonding layer 450.

A bond protecting o-ring 442 may be disposed between the lip 462 of the cooling base 460 and the electrostatic chuck 174. The bond protecting ring 442 protects the bonding layer 450 and other internal structures of the substrate support, such as the metal plate 410, from the plasma environment. The bond protecting o-ring 442 may be of a material suitable for a plasma environment and additionally is compressible. For example, the bond protecting o-ring 442 may be formed from a perfluoro polymer such as KALREZ®, CHEMRAZ® or XPE®.

A metal plate 410 is additionally disposed between the bond layers 450. The metal plate 410 may be bonded to the bottom 133 of the electrostatic chuck 174. The metal plate 410 may attain an operating temperature similar to that of the electrostatic chuck 174, i.e., the temperature of the metal plate 410 may be between about 180 degrees Celsius and about 300 degrees Celsius, such as 250 degrees Celsius. The metal plate 410 may have a thickness 412 similar to a diameter of the bond protecting o-ring 442. The metal plate 410 may be sized to fit within the lip 462 of the cooling base 460. Thus, as the bond protecting o-ring 442 is compressed, the metal plate 410 does not interfere with the compression of the bond protecting o-ring 442 by contacting the lip 462 of the cooling base 460.

The bonding layer 450 may have one or more layers. The layers may include gaskets, sheets and/or adhesives. The bonding layer 450 may optionally also include an o-ring vacuum seal 444. The o-ring vacuum seal 444 may contact the metal plate 410 and the cooling base 460. The o-ring vacuum seal 444 may be compressed to create a vacuum seal between the metal plate 410 and the cooling base 460. The vacuum seal created by the o-ring vacuum seal 444 prevents the loss of the vacuum in the processing region 110 of the plasma processing chamber 100 from escaping through the substrate support assembly 126. The vacuum seal created by the o-ring vacuum seal 444 may also prevent contamination or gases from entering the processing region 110. The o-ring vacuum seal 444 may be formed from a compressible material such as a perfluoro polymer or other suitable material. In one embodiment, the o-ring vacuum seal 444 is formed from CHEMRAZ® or XPE®. The o-ring vacuum seal 444 may compress up to about (10 to 28% of original size of the o ring) 35 mils. Alternately, the vacuum seal is made by the one or more layers of the bonding layer 450.

The one or more layers of the bonding layer 450 may form a composite gasket 470. The composite gasket 470 may be in contact with the metal plate 410 and the cooling base 460. The composite gasket 470 has a center portion 472 suitable for the electrical socket 260 to fit therethrough. The composite gasket 470 may be in contact with the cooling base 460. The composite gasket 470 may have an outer edge 452 and sized to be interior of the lip 462. The outer edge 452 and lip 462 may form a space 466 suitable for the o-ring vacuum seal 444 to fit therebetween. The composite gasket 470 may have a temperature gradient from the electrostatic chuck 174 to the cooling base 460 of about 170 degrees Celsius or greater, such as 270 degrees Celsius. The composite gasket 470 may have a thermal conductivity of about 0.10 W/mK to about 0.20 W/mk, such as about 0.20 W/mk. The composite gasket 470 thus prevents temperature loss from the electrostatic chuck 174 to the cooling base 460. The composite gasket 470 may be compressed between the metal plate 410 and cooling base 460. In some embodiments, the composite gasket 470 may be compression as much as 20%.

The composite gasket 470 may have one or more layers such as a first layer 420 and a second layer 430. The first layer 420 may be formed from a perfluoro material. The first layer 420 may be exposed to the temperature of the electrostatic chuck 174 through the metal plate 410, i.e., operating temperatures up to about 300 degrees Celsius. The first layer 420 may have a thickness 422 of between about 1 mm and about 2 mm. The first layer 420 may compress between about 200 microns and about 400 microns. In one embodiment, the thickness 422 of the first layer 420 is about 1 mm and the first layer compresses about 200 microns. In a second embodiment, the thickness 422 of the first layer 420 is about 2 mm and the first layer 420 compresses about 400 microns. The first layer 420 has a low thermal conductivity. In one embodiment, a top surface 421 of a 1 mm thick first layer 420 may have an operating temperature of about 250 degrees Celsius while a bottom surface 423 of the first layer 420 may have an operating temperature of about 150 degrees Celsius for a temperature gradient of about 100 degrees Celsius.

The second layer 430 of the composite gasket 470 may be formed from a perfluoro, porous graphite or silicone material. The second layer 430 may be in contact with and exposed to the temperatures of the first layer 420 and the cooling base 460. That is, the second layer 430 may be exposed to operating temperatures of about 150 degrees Celsius and about 80 degrees Celsius respectively. The second layer 430 may have a thickness 432 of about 0.5 mm to about 1.5 mm. The second layer 430 may be compressible to about 200 microns.

In one embodiment, the composite gasket 470 has a 2 mm thick perfluoro first layer 420 and a silicon second layer 430. In another embodiment, the composite gasket 470 has a 1 mm thick perfluoro first layer 420 and a 1 mm thick perfluoro second layer 430. In yet another embodiment, the composite gasket 470 has a 1 mm thick perfluoro first layer 420 and a 1 mm thick porous graphite second layer 430. The combination of the first and second layers 420, 430 of the composite gasket 470 have a compression substantial similar to the o-ring vacuum seal 444. In some embodiments, the first layer 420 is bonded to the metal plate 410 and the second layer 430 is bonded to the cooling base 460 and the o-ring vacuum seal 444 is not present.

Advantageously, the high operating temperature of the electrostatic chuck 174, temperatures exceeding 180 degrees Celsius such as about 250 degrees Celsius, do not compromise the composite gasket causing the vacuum seal to be broken or outgassing of the one or more layers forming the composite gasket 470. The composite gasket prevents contamination in the chamber or chamber downtime which may affect process yields and costs of operations.

While the foregoing is directed to implementations of the present invention, other and further implementations of the invention may be devised without departing from the basic scope thereof, and the scope thereof is determined by the claims that follow.

What is claimed is:

1. A substrate support assembly, comprising:
an electrostatic chuck having a workpiece supporting surface and a bottom surface;
a cooling base having a top surface; and
a bonding layer securing the bottom surface of the electrostatic chuck and the top surface of the cooling base, wherein the bonding layer comprises:
a first layer adhered to the bottom surface, wherein the first layer has an operating temperature that includes a temperature of about 300 degrees Celsius; and
a second layer disposed below the first layer, the second layer having a maximum operating temperature that is below 250 degrees Celsius.

2. The substrate support assembly of claim 1, wherein the bonding layer further comprises:
a third layer disposed below the second layer and bonded to the cooling base, wherein the third layer has a maximum operating temperature that is below about 200 degrees Celsius.

3. The substrate support assembly of claim 1, wherein the first layer has an operating temperature that includes temperatures between about 250 degrees Celsius and about 325 degrees Celsius.

4. The substrate support assembly of claim 1, wherein the thermal conductivity of the bonding layer is about 0.2 W/mK.

5. The substrate support assembly of claim 2, wherein the third layer has an operating temperature that includes temperatures between about 170 degrees Celsius and 60 degrees Celsius.

6. The substrate support assembly of claim 1, wherein the first layer is comprised of a perfluoro compound.

7. The substrate support assembly of claim 6, wherein a thickness of the first layer is between about 0.3 mm and about 5 mm.

8. The substrate support assembly of claim 1, wherein the second layer comprises polyimide or silicone.

9. The substrate support assembly of claim 1, wherein the second layer has a thermal conductivity of less than about 1 W/mK.

10. The substrate support assembly of claim 2, wherein the third layer comprises silicone.

11. The substrate support assembly of claim 1 further comprising:
an o-ring providing a seal between the electrostatic chuck and the cooling plate, the o-ring circumscribing the bonding layer.

12. The substrate support assembly of claim 2, wherein the coefficient of thermal expansion for the first layer is greater than that of the second layer or the third layer.

14. A substrate support assembly, comprising:
an electrostatic chuck having a heater, a workpiece support surface and a bottom surface;
a cooling base having a top surface; and
a bonding layer securing the bottom surface of the electrostatic chuck and the top surface of the cooling base, wherein the bonding layer comprises:
a first layer adhered to the bottom surface, wherein the first layer has an operating temperature that includes a temperature of about 300 degrees Celsius;
a second layer disposed below the first layer, the second layer having a maximum operating temperature that is lower that of the first layer; and
a third layer disposed below the second layer and in contact with the cooling plate, the third layer having a maximum operating temperature that is lower that of the second layer.

15. The substrate support assembly of claim 14, wherein the thermal conductivity of the bonding layer is about 0.2 W/mK.

16. The substrate support assembly of claim 14, wherein the third layer has an operating temperature that includes temperatures between about 170 degrees Celsius and 60 degrees Celsius.

17. The substrate support assembly of claim 14, wherein the first layer is comprised of a perfluoro polymer compound.

18. The substrate support assembly of claim 14, wherein the second layer comprises at least one of is one of a perfluoro polymer compound, silicone, polyimide and porous graphite.

19. The substrate support assembly of claim 14, wherein the second layer has a thermal conductivity of less than about 1 W/mK.

19. The substrate support assembly of claim 14, further comprising:
an o-ring providing a seal between the electrostatic chuck and the cooling plate, the o-ring circumscribing the bonding layer.

20. A substrate support assembly, comprising:
an electrostatic chuck having a heater, a workpiece support surface and a bottom surface;
a cooling plate having a top surface and lips along the top surface;
a metal plate disposed below the bottom surface of the electrostatic chuck; and
a bonding layer disposed between the metal plate and the top surface of the cooling plate; and
a first layer adhered to the bottom surface, wherein the first layer has an operating temperature that includes a temperature of about 300 degrees Celsius; and
a second layer disposed below the first layer, the second layer having a maximum operating temperature that is lower that of the first layer.

21. A substrate support assembly, comprising:
an electrostatic chuck having a workpiece supporting surface and a bottom surface;
a cooling base having a top surface; and
a bonding layer securing the bottom surface of the electrostatic chuck and the top surface of the cooling base, wherein the bonding layer comprises:
a first layer adhered to the bottom surface, wherein the first layer has an operating temperature that includes a temperature of about 300 degrees Celsius; and
a second layer stacked below the first layer and bonded to the cooling base, the second layer having a maximum operating temperature less than the maximum operating temperature of the first layer.

22. The substrate support assembly of claim 21, wherein the bonding layer further comprises:
a third layer disposed between the second layer and the first layer, the third layer having a maximum operating temperature that is below about 300 degrees Celsius.

23. The substrate support assembly of claim 21, wherein the thermal conductivity of the bonding layer is about 0.2 W/mK.

24. The substrate support assembly of claim 21, wherein the first layer is comprised of a perfluoro compound.

25. The substrate support assembly of claim 24, wherein the second layer comprises polyimide or silicone.

26. The substrate support assembly of claim 24, wherein the second layer comprises a perfluoro compound.
